(19) United States
(12) Patent Application Publication
(10) Pub. No.: US 2019/0157179 A1
(43) Pub. Date: May 23, 2019

(54) Case, Semiconductor Apparatus, Method for Manufacturing Case

(71) Applicant: Hitachi Automotive Systems, Ltd., Hitachinaka-shi, Ibaraki (JP)

(72) Inventors: Shinichi FUJINO, Hitachinaka-shi (JP); Takashi KUBOKI, Hitachinaka-shi (JP); Masaru KAWAI, Hitachinaka-shi (JP)

(21) Appl. No.: 16/091,583

(22) PCT Filed: Mar. 10, 2017
(86) PCT No.: PCT/JP2017/009645

§ 371 Date: Oct. 5, 2018

(30) Foreign Application Priority Data
Apr. 7, 2016 (JP) 2016-077150

(51) Int. Cl. H01L 23/367; H05K 7/20

(52) U.S. Cl. CPC H01L 23/3675; H05K 7/20927

(57) ABSTRACT

It is possible to improve heat dissipation of a semiconductor circuit to be inserted into a case. A case into which a semiconductor circuit is inserted, the case including: a heat dissipating portion having, on an inner side, a contact surface coming in contact with the semiconductor circuit; a thin portion formed to surround the contact surface and formed to be thinner than the heat dissipating portion; and a recess formed between the thin portion and the heat dissipating portion and recessed with respect to the contact surface, in which an inner surface of the recess is arranged between the contact surface and an inner surface of the thin portion in a thickness direction of the case.

### TECHNICAL FIELD

The present invention relates to a case, a semiconductor apparatus, and a method for manufacturing the case.

### BACKGROUND ART

There is a demand for power conversion apparatuses for hybrid vehicles, electric vehicles, and the like having higher output to enable further improvement of fuel economy, and accordingly power conversion apparatuses have been increased in current. Furthermore, there is also a demand for downsized power conversion circuit, leading to a problem of processing heat generated from the power conversion circuit, that is, waste heat processing.

PTL 1 discloses a configuration of cooling a semiconductor circuit by bringing the semiconductor circuit into contact with a cooling pipe via an insulating member and heat conductive grease.

### CITATION LIST

### Patent Literature

PTL 1: JP 4120876 B

### SUMMARY OF INVENTION

### Technical Problem

There is a high demand for improving heat dissipation of semiconductor circuits.

### Solution to Problem

According to a first aspect of the present invention, there is provided a case into which a semiconductor circuit is to be inserted, the case including: a heat dissipating portion having, on an inner side, a contact surface coming in contact with the semiconductor circuit; a thin portion formed to surround the contact surface and formed to be thinner than the heat dissipating portion; and a recess formed between the thin portion and the heat dissipating portion and recessed with respect to the contact surface, in which an inner surface of the recess is arranged between the contact surface and an inner surface of the thin portion in a thickness direction of the case.

According to a second aspect of the present invention, there is provided a semiconductor apparatus including: a semiconductor circuit having a semiconductor element; and a case to accommodate the semiconductor circuit, in which the case includes: a heat dissipating portion having a contact surface coming in contact with the semiconductor circuit; a thin portion formed to surround the contact surface and formed to be thinner than the heat dissipating portion; and a recess formed between the thin portion and the heat dissipating portion and recessed with respect to the contact surface, and an inner surface of the recess is arranged between the contact surface and an inner surface of the thin portion in a thickness direction of the case.

According to a third aspect of the present invention, there is provided a method for manufacturing a case into which a semiconductor circuit is inserted, the method including forming each of: a heat dissipating portion having, on an inner side, a contact surface coming in contact with the semiconductor circuit; a thin portion formed to surround the contact surface and formed to be thinner than the heat dissipating portion; and a recess formed between the thin portion and the heat dissipating portion and recessed with respect to the contact surface to be arranged so as to allow an inner surface of the recess to be arranged between the contact surface and an inner surface of the thin portion in a thickness direction of the case, so as to be formed individually in the case, and performing cutting processing on the contact surface of the case in a state where the case is supported by a jig processed in the recess.

### Advantageous Effects of Invention

According to the present invention, it is possible to improve the heat dissipation of a semiconductor circuit to be inserted into a case.

### BRIEF DESCRIPTION OF DRAWINGS

FIG. 1 is a diagram illustrating an external view of a case 24.

FIG. 2 is a diagram illustrating a structure of the case 24.

FIG. 3 is a diagram illustrating a structure of the case 24.

FIG. 4(a) is an external view of the case 24 before processing, FIG. 4(b) is a cross sectional view taken along line IVb-IVb of FIG. 4(a), and FIG. 4(c) is a cross sectional view of taken along line IVc-IVc in FIG. 4(a).

FIG. 5(a) is an external view of the case 24 after a first processing step, FIG. 5(b) is a cross sectional view taken along line Vb-Vb of FIG. 5(a), and FIG. 5(c) is a cross sectional view taken along line Vc-Vc in FIG. 5(a).

FIG. 6(a) is an external view of the case 24 after a second processing step, FIG. 6(b) is a cross sectional view taken along line VIb-VIb of FIG. 6(a), and FIG. 6(c) is a cross sectional view taken along line VIc-VIc in FIG. 6(a).

FIG. 7(a) is an external view of the case 24 after a third processing step, FIG. 7(b) is a cross sectional view taken along line VIIb-VIIb of FIG. 7(a), and FIG. 7(c) is a cross sectional view taken along line VIIIc-VIIIc in FIG. 7(a).

FIG. 8 is a diagram illustrating an example of performing cutting processing on the case 24 described above.

FIG. 9 is a diagram illustrating a relationship between the first retainer 301, the second retainer 302, and fins 25 obtained from a viewpoint indicated by IX in FIG. 8.

FIG. 10 is a diagram illustrating a configuration of a semiconductor circuit to be inserted in the case 24.

FIG. 11 is a diagram with an upper heat dissipation plate 3a and an upper heat dissipation plate 3b added to the semiconductor circuit illustrated in FIG. 10.

FIG. 12 is a diagram illustrating a step of integrating the case 24 and a semiconductor circuit 100.

FIG. 13 is a diagram illustrating a state after an adhesive sheet 23 in FIG. 12 is joined.

FIG. 14 is a diagram illustrating an external view of a semiconductor cooling apparatus 300.

FIG. 15 is a diagram illustrating a state in which the case 24 is inserted in the semiconductor cooling apparatus 300.

FIG. 16 is a diagram illustrating a stepped portion 204 and an arrangement position of fins 25 in a first modification.

FIG. 17 is a diagram illustrating a stepped portion 204 and an arrangement position of fins 25 in a second modification.

### DESCRIPTION OF EMBODIMENTS

### Embodiments

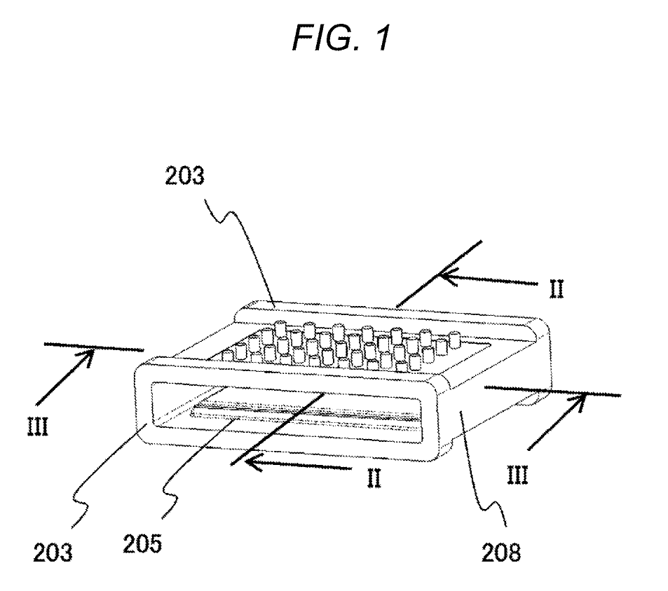

Embodiments of a case according to the present invention will be described below with reference to FIGS. 1 to 15.

(Configuration of Case 24)

FIG. 1 is a diagram illustrating an external view of a case 24 in the present embodiment. The case 24 is a CAN-type hexagonal body having a substantially quadrangular cross section in a tubular shape. Each of three pairs of surfaces of the case 24 is referred to as an opening surface, a side wall surface, and a heat dissipation surface. These surfaces are perpendicular to each other in the case 24.

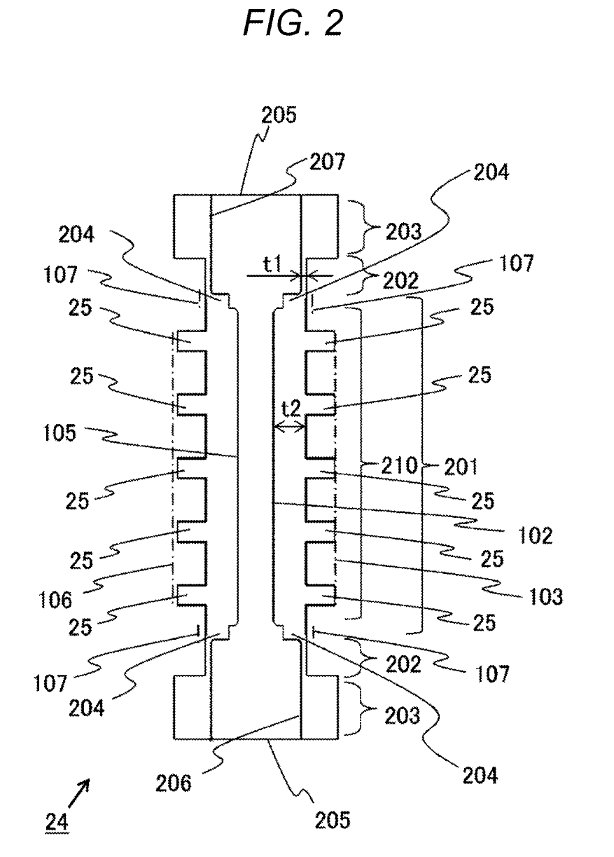

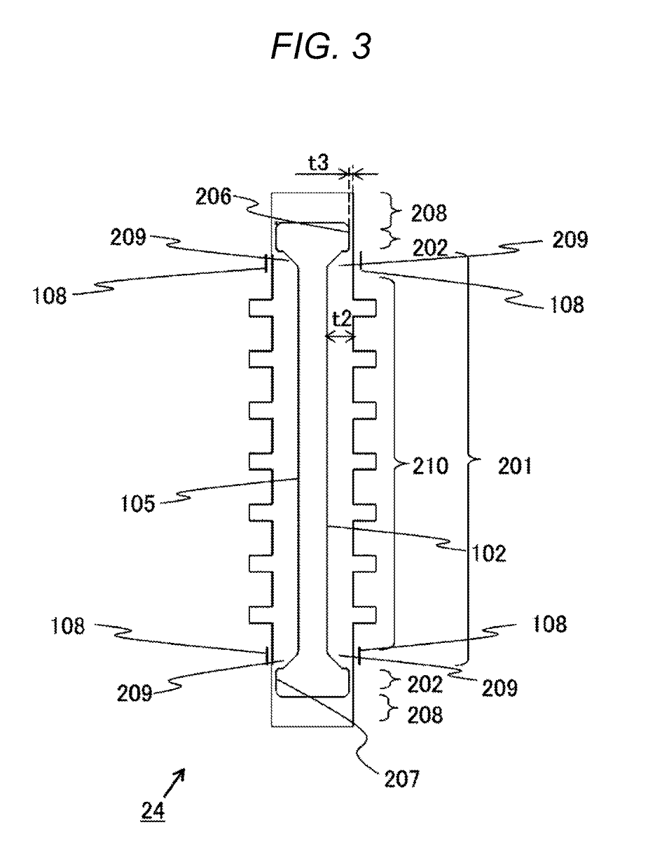

Each of the opening surfaces, that is, a pair of surfaces of the case 24, includes an opening portion 205. A flange 203 is formed on each of the opening portions 205. Side walls 208 are formed on side wall surfaces, that is, the other pair of surfaces, and both ends of the side wall 208 are connected to both ends of the flange 203, respectively. Fins 25 for heat dissipation are provided on the heat dissipation surface which is the final pair of surfaces. A II-II cross section of the case 24 is illustrated in FIG. 2, while a III-III cross section is illustrated in FIG. 3.

A structure of the case 24 will be described with reference to FIGS. 2 to 3.

Upper and lower ends in FIG. 2 are the opening portions 205, and inner portions of the case 24 continuing from the opening portion 205 are the inner wall 206 and the inner wall 207. The upper and lower ends in FIG. 3 are side walls 208. On the surface of each of the inner walls 206 and 207 surrounded by the flange 203 and the side wall 208, a thick portion 201 is formed to protrude inward from each of the inner walls 206 and 207. Thin portions 202 are formed on an outer periphery of the thick portion 201, that is, above and below the thick portion 201 in FIGS. 2 to 3. A thickness t1 of the thin portion 202 illustrated in FIG. 2 and a thickness t3 of the thin portion 202 illustrated in FIG. 3 may be the same or different. The thickness t1 or t3 of the thin portion 202 is thinner than a thickness t2 of the thick portion 201 excluding the fins 25, which will be described below. The thin portion 202 connects the flange 203 and the side wall 208. The surfaces protruding into the inside of the thick portion 201 are formed flat by cutting processing to be described below, so as to form contact surfaces 102 and 105 on the inner walls 206 and 207, respectively. The contact surfaces 102 and 105 are surfaces to be directly joined to a power semiconductor or the like to be inserted into the case 24, and thus are formed flat so as to enable high heat transfer.

A plurality of fins 25 is formed on an opposite side of each of the contact surface 102 and the contact surface 105 of the thick portion 201, that is, on the outside of the case 24. A right end surface 103, that is, a virtual surface formed by connecting ends of the fins 25 on the right side in the figure is formed in parallel to the contact surface 102 formed on the inner wall 206 on the right side in the drawing. Similarly, a left end surface 106, that is, a virtual surface formed by connecting ends of the fins 25 on the left side in the drawing is formed in parallel to the contact surface 105 formed on the inner wall 207 on the left side in the figure.

The inner surface of the thin portion 202 corresponds to the inner walls 206 and 207 and is formed to be substantially flush with the inner surface of the flange 203. The outer surface of the thin portion 202, that is, the surface opposite to the inner walls 206 and 207 is formed to be substantially flush with a base surface of the fin 25.

A stepped portion 204 is formed at a connecting portion between the thin portion 202 and the thick portion 201, being an outer periphery of the thick portion 201 and connected to the opening portion 205. More specifically, on the contact surface 102 side illustrated on the right side of FIG. 2, the stepped portion 204 is formed in a space sandwiched between the two surfaces, namely, the contact surface 102 and the inner wall 206, at the two upper and lower portions on the right side of FIG. 2. On the contact surface 105 side illustrated on the left side of FIG. 2, the stepped portion 204 is formed in a space sandwiched between the two surfaces, namely, the contact surface 105 and the inner wall 207, at the two upper and lower portions on the left side of FIG. 2. Hereinafter, the outer surface of the stepped portion 204 will be referred to as a projection surface 107.

A stepped portion 209 is formed at a connecting portion between the thin portion 202 and the thick portion 201, being an outer periphery of the thick portion 201 and connected to the side wall 208. More specifically, on the contact surface 102 side illustrated on the right side of FIG. 3, the stepped portion 209 is formed in a space sandwiched between the two surfaces, namely, the contact surface 102 and the inner wall 206, at the two upper and lower portions on the right side of FIG. 3. Similarly, on the contact surface 105 side illustrated on the left side of FIG. 3, the stepped portion 209 is formed in a space sandwiched between the two surfaces, namely, the contact surface 105 and the inner wall 207, at the two upper and lower portions on the left side of FIG. 3. Hereinafter, the outer surface of the stepped portion 209 will be referred to as a projection surface 108.

A region excluding the stepped portions 204 and 209 from the thick portion 201 is a heat dissipating portion 210 that dissipates heat from a heating element such as a power semiconductor to be inserted into the case 24. As described above, the stepped portions 204 and 209 are provided at several outer peripheral portions of the thick portion 201. Therefore, the stepped portions 204 and 209 are provided between the heat dissipating portion 210 and the thin portion 202 at a certain position, while the heat dissipating portion 210 and the thin portion 202 are adjacent to each other at another position.

The fins 25 are disposed outside the case 24 and inside a boundary between the thick portion 201 and the thin portion 202. Furthermore, the fins 25 are not disposed on the projection surface 107 of the stepped portion 204 or the projection surface 108 of the stepped portion 209. In other words, the fins 25 are provided in the heat dissipating portion 210.

(Step for Molding Case 24)

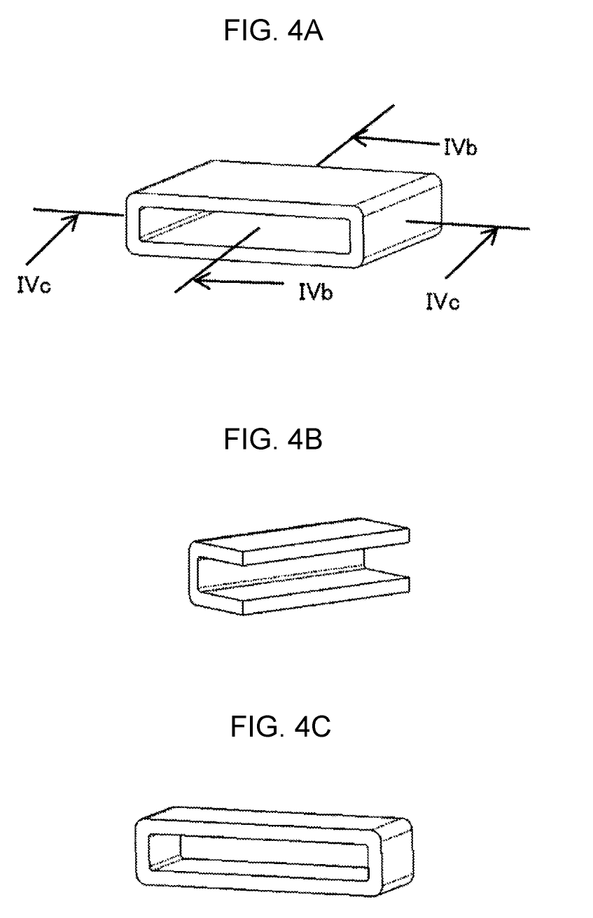

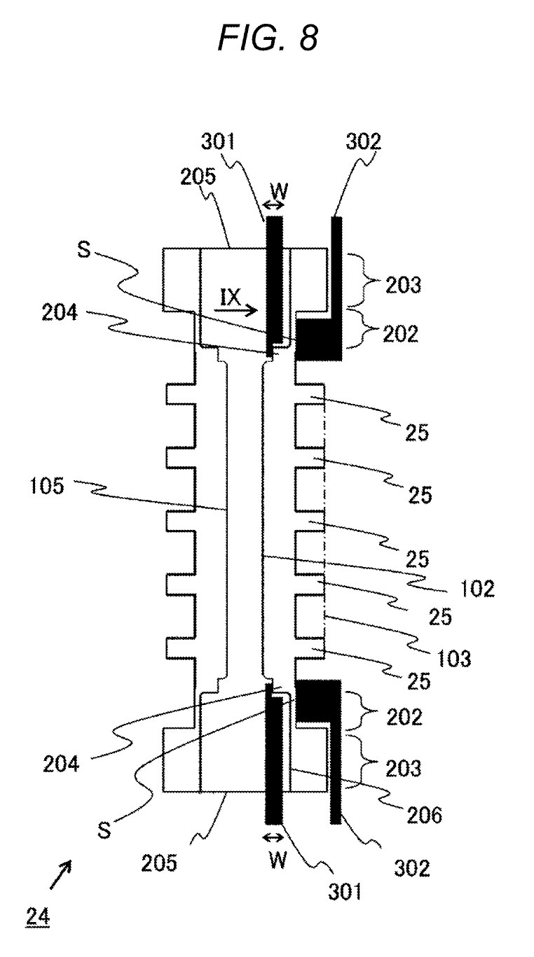

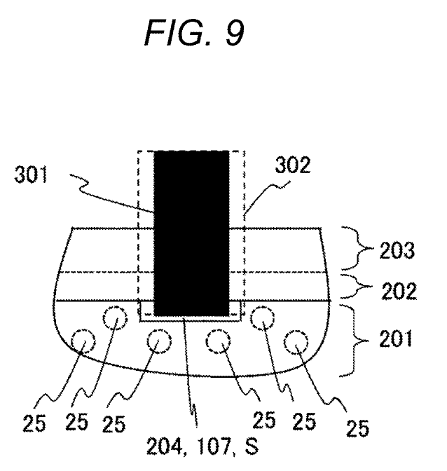

A method of creating the case 24 illustrated in FIGS. 1 to 3 will be described with reference to FIGS. 4 to 9. As will be described below, molding is performed by the steps illustrated in FIGS. 4 to 7, and cutting processing is performed by the steps illustrated in FIGS. 8 to 9.

FIGS. 4 to 7 are diagrams illustrating steps for molding the case 24 described above.

FIG. 4 is a diagram illustrating the case 24 before processing. FIG. 4(a) is an external view of the case 24 before processing, FIG. 4(b) is a cross sectional view taken along line IVb-IVb of FIG. 4(a), and FIG. 4(c) is a cross sectional view of taken along line IVc-IVc in FIG. 4(a). As illustrated in FIGS. 4(a) to 4(c), the case 24 before processing has no irregularities on the surface, that is, neither on the outer side nor on the inner side.

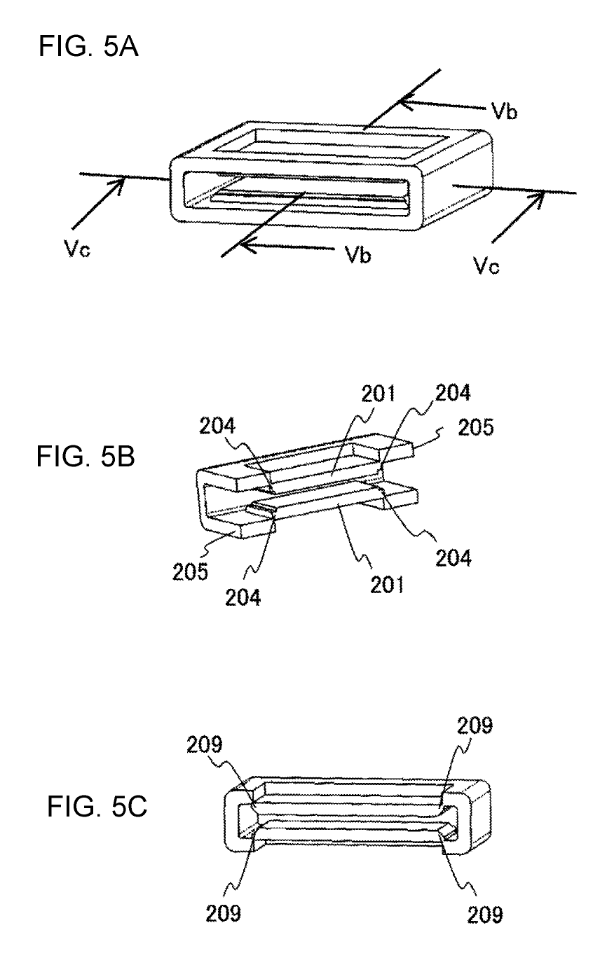

FIG. 5 is a diagram illustrating the case 24 that has undergone a first processing step for forming the thick portion 201. FIG. 5(a) is an external view of the case 24 after first processing step, FIG. 5(b) is a cross sectional view taken along line Vb-Vb of FIG. 5(a), and FIG. 5(c) is a cross sectional view taken along line Vc-Vc in FIG. 5(a). In the first processing step, for example, molding is performed from the outer periphery toward the inner side by forging molding, thereby simultaneously forming the upper and lower thick portions 201. In addition, the stepped portions 204 and 209 are simultaneously molded by the above forging molding. In this forging molding, a core mold is inserted from both sides of the two opening portions 205. Note that while FIG. 5 and FIGS. 6 to 7 to be described below illustrate the stepped portions 204 and 209 existing over the entire circumference, the stepped portions 204 and 209 in the present embodiment are provided only at several portions as described above.

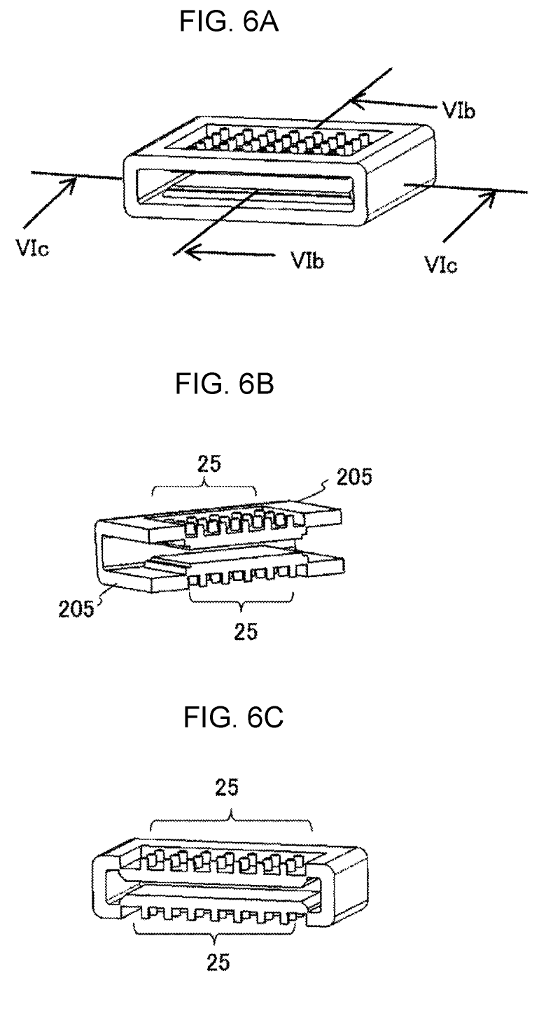

FIG. 6 is a diagram illustrating the case 24 that has undergone a second processing step for forming the fin 25. FIG. 6(a) is an external view of the case 24 after second processing step, FIG. 6(b) is a cross sectional view taken along line VIb-VIb of FIG. 6(a), and FIG. 6(c) is a cross sectional view taken along line VIc-VIc in FIG. 6(a). In the second processing step, for example, the thick portion 201 is pressed by forging molding, and upper and lower fins 25 are simultaneously molded. As described above, since the fins 25 are disposed inside the boundary between the thick portion 201 and the thin portion 202, the fin 25 can be molded by a material flow of the thick portion 201 by pressurization in forging molding. In this forging molding, a core mold is inserted from both sides of the two opening portions 205.

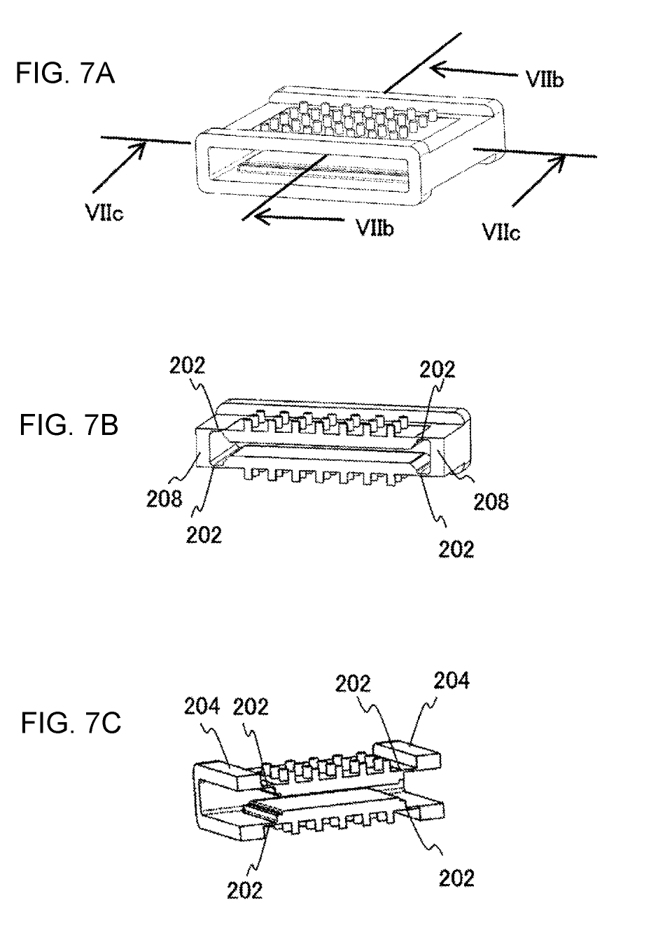

FIG. 7 is a diagram illustrating the case 24 that has undergone a third processing step for forming the thin portion 202, the flange 203, and the side wall portion 208. FIG. 7(a) is an external view of the case 24 after the third processing step, FIG. 7(b) is a cross sectional view taken along line VIIb-VIIb of FIG. 7(a), and FIG. 7(c) is a cross sectional view taken along line VIIIc-VIIIc in FIG. 7(a). In the third processing step, for example, in the upper and lower two surfaces, a portion around the fin 25 is cut to a base surface of the fin 25 excluding a portion to be the flange 203. With this processing, the thin portion 202, the flange 203, and the side wall portion 208 are formed.

(Step for Cutting Case 24)

When the third processing step illustrated in FIG. 7 is finished, end surfaces of the fins 25 and the contact surfaces 102 and 105 are processed by cutting processing described below so that the flatness of the contact surfaces 102 and 105 and the parallelism between the end surface of the fins 25 and the contact surfaces 102 and 105 satisfy predetermined standard values. With this processing, the case 24 illustrated in FIGS. 1 to 3 is completed.

Here, there is a problem of chucking, that is, how the case 24 is to be fixed in the cutting processing. Although the thick flange 203 is provided on an outer peripheral portion of the case 24, this flange 203 cannot be a position to be chucked for processing. This is because the thin portion 202 provided between the vicinity of the fin 25 to be processed and the flange 203 is easy to bend, and the vicinity of the fin 25 to be processed would not be fixed even when the flange 203 is chucked. Accordingly, the stepped portion 204 is to be used as a chuck as follows.

FIG. 8 is a diagram illustrating an example of performing the above-described cutting processing of the case 24, more specifically, cutting processing on the right end surface 103 and the contact surface 102 of the fin 25 on the right side in the drawing. In FIG. 8, a first retainer 301 and a second retainer 302 are jigs for fixing the case 24.

The first retainer 301 is inserted into the case 24 from the opening portion 205, and supports and fixes the case 24 from the inside. The first retainer 301 is a rod-shaped member having a depression at its end. The depression provided at the end of the first retainer 301 comes in contact with the stepped portion 204, thereby holding the case 24 in cooperation with the second retainer 302. The first retainer 301 comes in contact with the case 24 only at the above-described depression. Since the cutting processing tool for processing the contact surface 102 and the contact surface 105 is inserted from the opening portion 205 in a state where the first retainer 301 fixes the case 24, a width W of the first retainer 301 is limited to a maximum width of a space sandwiched between the two surfaces, namely, the contact surface 102 and the inner wall 206. In other words, the width W of the first retainer 301 is defined as the maximum width of the space sandwiched between the contact surface 102 and the inner wall 206, not limited by the thickness of the thick portion 201 or the stepped portion 204, making it possible to increase rigidity.

The second retainer 302 supports and fixes the case 24 from the outside. The second retainer 302 comes in contact with the case 24 via a contact surface S, thereby holding the case 24 in cooperation with the first retainer 301. Next, as will be described with reference to FIG. 9, the contact surface S fixes the case 24 to allow the fins 25 to be exposed. The surface of the thin portion 202 on the side opposite to the inner wall 206, that is, the outer surface of the case 24 is formed to be substantially flush with the base surface of the fin 25. This allows the contact surface S of the second retainer 302 to be in contact with both the surface of the thin portion 202 opposite to the inner wall 206 and the base surface of the fin 25. That is, the contact surface S can be widened to enable the case 24 to be firmly fixed, making it possible to suppress deformation of the case 24 at processing, leading to achievement of high-speed and high accuracy in the processing.

With the case 24 fixed using the first retainer 301 and the second retainer 302 as described above, it is possible to continuously or simultaneously process the contact surface 102 and the right end surface 103 without removing the case 24 from the jig once fixed, enabling the contact surface 102 and the right end surface 103 to be processed in parallel. Furthermore, since the first retainer 301 is inserted from each of the two opening portions 205, the case 24 can be more firmly fixed as compared with a method of fixing with the jig from only one direction. This can suppress deformation of the case 24 at the time of processing and can achieve high speed and high accuracy in the processing. Note that it is also allowable to process both the contact surface 102 and the right end surface 103 on the basis of a separately provided reference surface, or one of the surfaces may be processed with the other surface defined as the reference surface.

Note that in order to process the left end surface 106 and the contact surface 105 of the fin 25 on the left side in the figure, the positions bilaterally symmetrical to FIG. 8 are chucked by the first retainer 301 and the second retainer 302.

FIG. 9 is a diagram illustrating a relationship between the first retainer 301, the second retainer 302, and the fins 25 obtained from a viewpoint indicated by IX in FIG. 8. Note that in FIG. 9, the second retainer 302 and the fins 25 are indicated by broken lines. As described above, the fins 25 are not disposed on the projection surface 107 of the stepped portion 204. This configuration enables the contact surface S of the second retainer 302 to be disposed immediately below the portion where the stepped portion 204 of the first retainer 301 is fixed to rigidly fix the case 24, making it possible to suppress deformation of the case 24 at the time of processing, leading to achievement of high speed and high accuracy in the processing.

(Insertion of Semiconductor into Case 24)

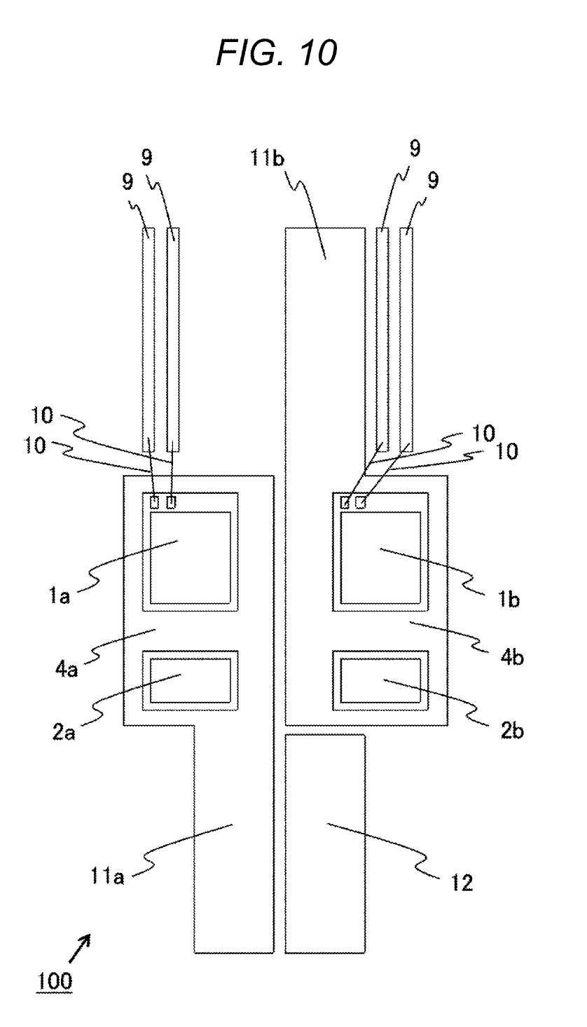

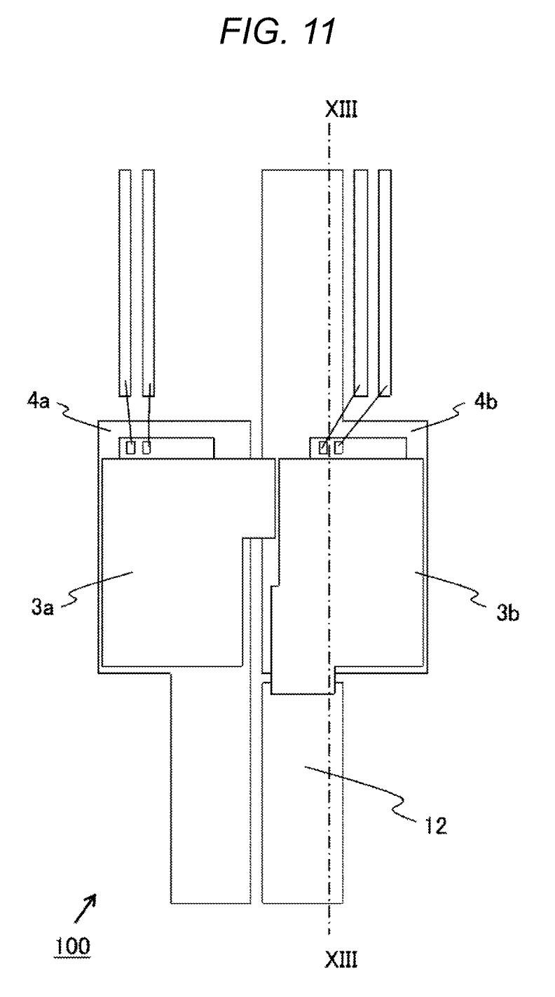

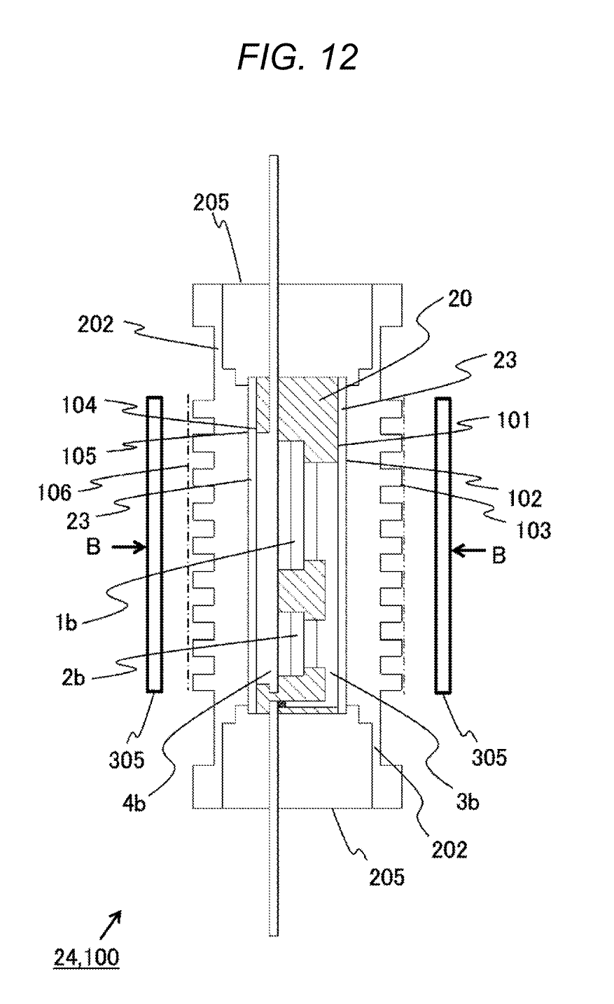

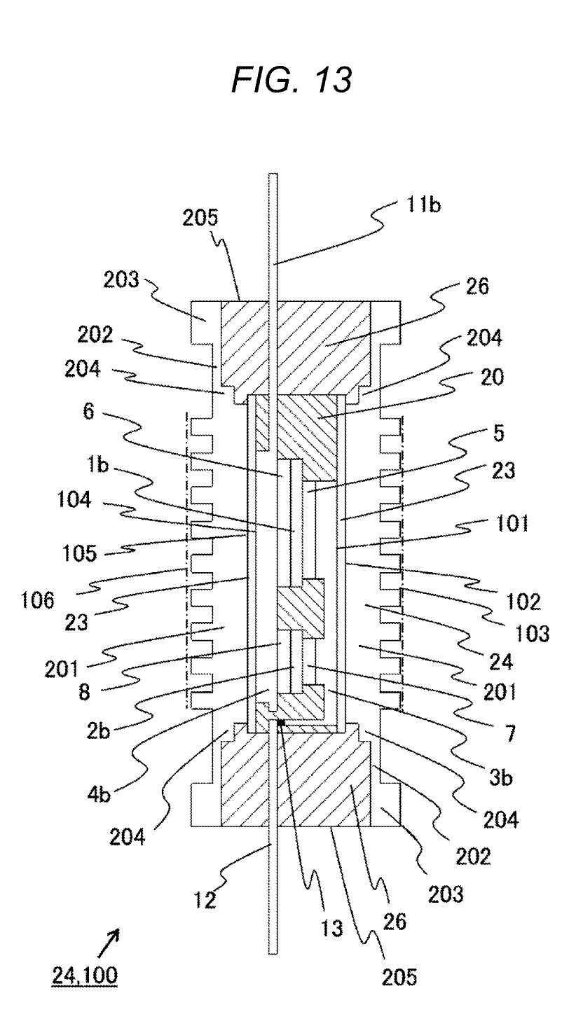

A configuration of a semiconductor circuit to be inserted into the case 24 will be described with reference to FIGS. 10 to 11, and then insertion of the semiconductor into the case 24 will be described with reference to FIGS. 12 to 13.

FIGS. 10 and 11 are diagrams illustrating a configuration of a semiconductor circuit to be inserted in the case 24. The semiconductor circuit to be inserted into the case 24 has a configuration including components stacked in a height direction. Hereinafter, a configuration excluding upper-stage components will be described with reference to FIG. 10, and the configuration including the upper-stage components will be described with reference to FIG. 11.

In FIG. 10, an IGBT chip 1a and an SFD chip 2a are connected to a lower heat dissipation plate 4a respectively using an IGBT lower surface solder described below and an SFD lower surface solder described below. An IGBT chip 1b and an SFD chip 2b are connected to a lower heat dissipation plate 4b respectively using the IGBT lower surface solder described below and the SFD lower surface solder described below. Surfaces of the lower heat dissipation plate 4a and the lower heat dissipation plate 4b, on which no chips are stacked, that is, surfaces on the back side in the drawing constitute a contact surface 104 to be joined with an adhesive sheet 23 described below. Control terminals such as gate terminals of the IGBT chip 1a and the IGBT chip 1b are connected to a gate pin 9 by an aluminum wire 10. A bus bar 11a is integrally formed on the lower heat dissipation plate 4a, while a bus bar 11b is integrally formed on the lower heat dissipation plate 4b. Next to the bus bar 11a, a bus bar 12 for electric connection with the outside is disposed similarly to the bus bar 11. The gate pin 9 and the bus bars 11a, 11b, and 12 are arranged on a same plane. The gate pin 9, the bus bars 11a, 11b, 12, and the lower heat dissipation plates 4a and 4b are obtained by punching a same single plate formed by pultrusion or the like.

FIG. 11 is a diagram with an upper heat dissipation plate 3a and an upper heat dissipation plate 3b added to the semiconductor circuit illustrated in FIG. 10. The upper heat dissipation plate 3a and the upper heat dissipation plate 3b are joined to individual chips using an IGBT upper surface solder and an SFD upper surface solder described below. Surfaces of the upper heat dissipation plate 3a and the upper heat dissipation plate 3b, on which no chips are stacked, that is, surfaces on the front side in the drawing constitute a contact surface 101 to be joined with the adhesive sheet 23 described below. The upper heat dissipation plate 3a is electrically connected to the lower heat dissipation plate 4b, and the upper heat dissipation plate 3b has a protrusion extending to the bus bar 12 and is electrically connected to the bus bar 12 with a solder 13 (FIG. 13). A semiconductor circuit 100 is molded using a mold described below in order to fix the relative positions of the components. As will be described in detail below, the contact surface 101 and the contact surface 104 to be joined to the adhesive sheet 23 are exposed from the mold.

FIG. 12 is a diagram illustrating a step of inserting a molded semiconductor circuit into the case 24 and integrating the case 24 with the semiconductor circuit 100. In FIG. 12, the adhesive sheet 23 having heat dissipating and insulating properties is respectively attached to the contact surface 102 and the contact surface 105 of the case 24 illustrated in FIG. 1, and the semiconductor circuit 100 is inserted between the adhesive sheets 23. In FIG. 12, the semiconductor circuit 100 illustrated in FIGS. 10 to 11 is rotated by 90 degrees in the depth direction in illustration and inserted into the case 24. After insertion is performed onto the case 24, both surfaces of the right end surface 103 and the left end surface 106 are pressed in a direction of arrow B by the pressing jig 305 to deform the thin portion 202. This brings the adhesive sheet 23 and the contact surface 102 into close contact with each other, and brings the adhesive sheet 23 and the contact surface 105 into close contact with each other. The adhesive sheet 23 is heated in a pressurized state, that is, the state where the adhesive sheet 23 and the contact surface 102 come into close contact with each other and the adhesive sheet 23 and the contact surface 105 come into contact with each other, allowing the contact surfaces 101, 102, 104, and 105 to be joined with the adhesive sheet 23. Since the contact surfaces 101, 102, 104, and 105 are parallel to each other and the left and right end surfaces 103 and 106 are parallel to each other, uniform pressure is generated on the adhesive sheet 23. After the adhesive sheet 23 is joined, a case mold 26 is sealed.

With joining with the adhesive sheet 23, the thin portion 202 is deformed at the time of pressurization in the direction of arrow B by the pressing jig 305, leading to suppression of deformation of the contact surfaces 102 and 104, maintaining a parallel state between the contact surfaces 102 and 104. In addition, the contact surfaces 101, 102, 104, and 105 and the left and right end surfaces 103 and 106 are respectively parallel to each other during joining, uniform pressure is generated on the adhesive sheet 23. As a result, the adhesive sheet after joining has a high joining strength, with no joining defect such as peeling of the joint, leading to high joining reliability in the adhesive sheet 23.

Furthermore, the adhesive sheet 23 absorbs parallel misalignment between the contact surfaces 101 and 102 and between the contact surfaces 104 and 105 and absorbs warps of the contact surfaces 101, 102, 104, and 105, and then joins the contact surface 101 with 102, and the contact surface 104 with 105. Meanwhile, with large parallel misalignment or warpage and the thin adhesive sheet 23, parallel misalignment or warpage cannot be absorbed, leading to an occurrence of a joining failure such as peeling after joining. On the other hand, while the thick adhesive sheet 23 makes it possible to absorb parallel misalignment and warpage, the heat conductivity of the adhesive sheet 23 is lowered, leading to decreased heat dissipation of the IGBT chip 1 and the SFD chip 2. In the embodiment, however, the contact surfaces 102 and 105 of the case 24 and the left and right end surfaces 103 are 106 are machined, with no parallel misalignment or warpage. In addition, since the contact surfaces 101 and 104 are processed with high accuracy, for example, by grinding, there is no parallel misalignment or warpage in a similar manner. Therefore, with substantially no parallel misalignment or warpage, it is possible to suppress joining defects such as peeling after joining, enabling high joining reliability. Furthermore, the adhesive sheet 23 needs to perform substantially no absorption of parallel misalignment or warping, and thus can achieve reduction of thickness and excellent heat transfer property, leading to high heat dissipation in the IGBT chip 1 and the SFD chip 2.

FIG. 13 is a diagram illustrating a state after the adhesive sheet 23 in FIG. 12 is joined. The cross section of the semiconductor circuit 100 in FIG. 13 is a cross section taken along line XIII-XIII in FIG. 11.

In FIG. 13, the IGBT chip 1 is joined onto one surface of the upper heat dissipation plate 3 having heat dissipation via an IGBT upper surface solder 5. The other surface of the IGBT 1 is joined onto the one surface of the lower heat dissipation plate 4b having heat dissipation via the IGBT lower surface solder 6. The SFD chip 2 is joined onto the surface of the upper heat dissipation plate 3b to which the IGBT chip 1 is joined, via an SFD upper surface solder 7. The other surface of the SFD 2 is joined onto the surface of the lower heat dissipation plate 4b to which the IGBT chip 1 is joined, via an SFD lower surface solder 8. The surface side to which the upper heat dissipation plate 3b, the IGBT chip 1 and the SFD chip 2 of the lower heat dissipation plate 4b are connected is molded with a mold 20 formed of an insulating organic material.

The surface of the upper heat dissipation plate 3b opposite to the surface to which the IGBT chip 1 and the SFD chip 2 are connected, that is, the above-described contact surface 101 is exposed from the mold 20. The surface being the mold 20 covering the outer circumference of the exposed surface of the upper heat dissipation plate 3b and being flush with the contact surface 101 constitutes the contact surface 101. The surface of the lower heat dissipation plate 4 opposite to the surface to which the IGBT chip 1 and the SFD chip 2 are connected, that is, the above-described contact surface 104 is exposed from the mold 20. The surface being the mold 20 covering the outer circumference of the exposed surface of the lower heat dissipation plate 4b and being flush with the contact surface 104 constitutes the contact surface 104.

The contact surface 101 is joined to the contact surface 102 of the thick portion 201 of the case 24 by the adhesive sheet 23. Furthermore, the contact surface 104 is joined to the contact surface 105 of the thick portion 201 of the case 24 by the adhesive sheet 23. The mold 20 and the portions protruding from the contact surfaces 102 and 103, 105 and 106 of the adhesive sheet 23, and the stepped portions 204 and 209 of the case 24 are sealed with a sealant 206. Within the mold 20, the bus bar 12 joined to the upper heat dissipation plate 3 via the solder 13 extends in the direction of the opening portion 205 in parallel to the contact surfaces 101 and 102, and protrudes from the opening portion 205 to be connected to the outside. Similarly, the bus bar 11b integral with the lower heat dissipation plate 4 extends in the direction of the opening portion 205 in parallel to the contact surfaces 101 and 102, and protrudes from the opening portion 205 to be connected to the outside.

(Configuration Example of Semiconductor Cooling Apparatus 300)

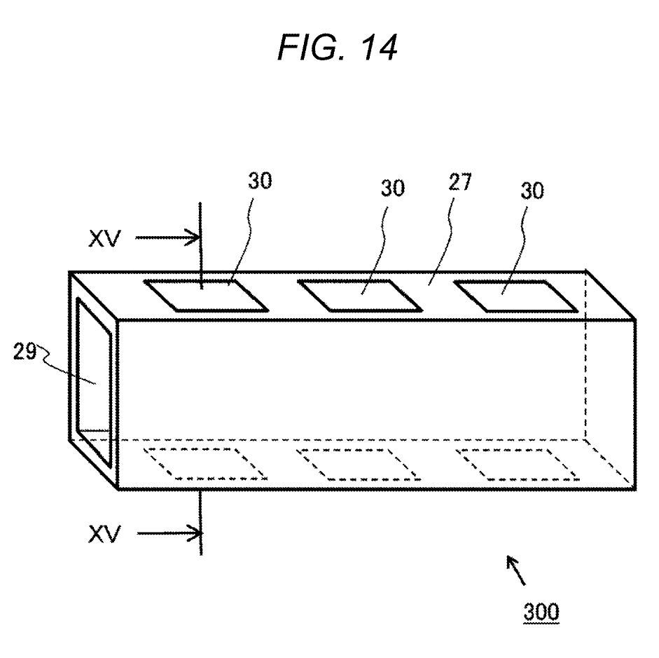

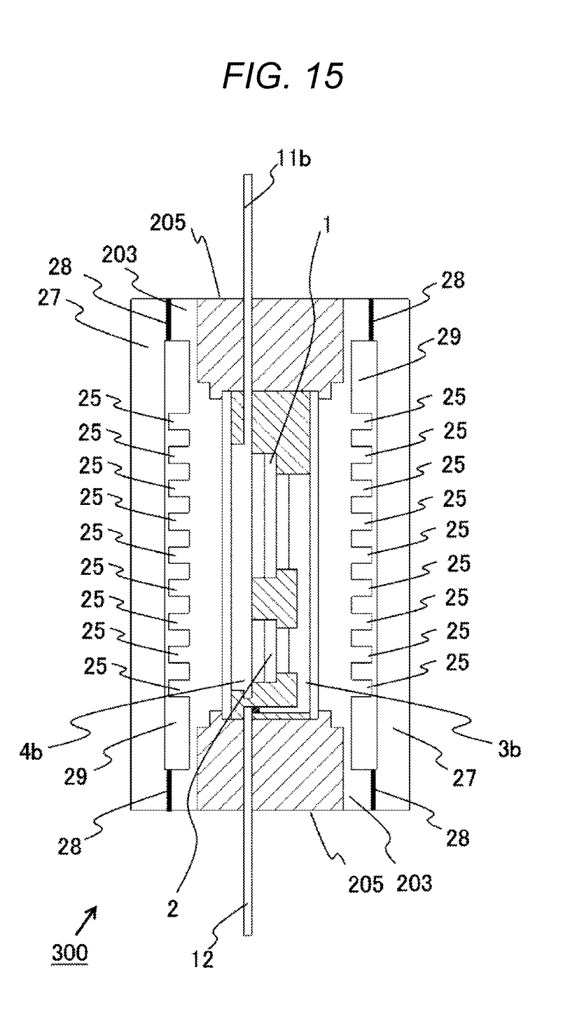

FIGS. 14 to 15 are diagrams illustrating an exemplary semiconductor cooling apparatus 300 using the case 24 illustrated in FIG. 13, that is, the case 24 in which the semiconductor circuit 100 is inserted. FIG. 14 is a diagram illustrating an external view of the semiconductor cooling apparatus 300. FIG. 15 is a diagram illustrating a state in which the case 24 is inserted in the semiconductor cooling apparatus 300.

As illustrated in FIG. 14, the semiconductor cooling apparatus 300 includes a water passage 29 through which a coolant liquid flows from the left to the right in the figure, an outer shell portion 27 constituting the water passage 29, and a plurality of pairs of insertion holes 30 formed on the outer shell portion 27, through each of which the case 24 is to be inserted. The pair of insertion holes 30 vertically penetrates the water passage 29. The case 24 is inserted into the pair of insertion holes 30 to cool the semiconductor circuit 100 in the case 24. Although the case 24 and the semiconductor circuit 100 are not illustrated in FIG. 14, the bus bar 11b protrudes from the upper portion of the outer shell portion 27 and the bus bar 12 protrudes from the lower portion thereof for example in a state where the case 24 illustrated in FIG. 13 is inserted into the insertion hole 30.

Since the semiconductor cooling apparatus 300 can cool a plurality of the semiconductor circuits 100 with a single tube, it is possible to simplify the water passage structure. Furthermore, the semiconductor circuit 100 is cooled with a small space, making it possible to downsize a power conversion apparatus incorporating the semiconductor apparatus.

As illustrated in FIG. 15, the water passage 29 is formed by the outer shell portion 27. More specifically, the water passage 29 is constituted with the flange 203, the outer shell portion 27, and a sealing material 28. For example, the coolant liquid moves in the water passage 29 from the front side to the back side in the drawing allowing the fin 25 to be cooled by this coolant liquid. Accordingly, the IGBT chip 1 and the SFD chip 2 are cooled via the upper heat dissipation plate 3, the lower heat dissipation plate 4, and the adhesive sheet 23. The IGBT chip 1 and the SFD chip 2 are cooled from the directions of the two surfaces, namely, the upper heat dissipation plate 3 side and the lower heat dissipation plate 4 side, enabling suppression of temperature rise. Furthermore, there is no inclusion having low heat transfer property such as grease from the positions of the IGBT chip 1 and the SFD chip 2 to the water passage 29, leading to excellent heat dissipation.

The two opening portions 205 of the case 24 from which the bus bars 11b and 12 protrude are divided from the water passage 29 constituted by the flange 203 and the outer shell portion 27, and furthermore, ends from which the bus bars 11b and 12 protrude do not interfere with the water passage 29. With this configuration, the bus bars 11b and 12 are easily connected to the outside. This makes it possible to achieve high flexibility in electrical connection, enabling high productivity of the power conversion apparatus incorporating the semiconductor apparatus of the present invention.

In addition, as described above, the case 24 is integrally formed of a pipe material, having no connecting portion. That is, there is only one joint in the water passage 29, that is, the sealing material 28 for joining the outer shell portion 27 and the case 24, making it possible to achieve high reliability in the water passage.

According to the above-described embodiment, the following operational effects can be obtained. (1) The case 24 includes: the heat dissipating portion 210 having contact surfaces 102 and 105 coming in contact with the semiconductor circuit 100; thin portions 202 and 206 formed to surround the contact surfaces 102 and 105 and formed to be thinner than the heat dissipating portion 210; and recess, namely, the stepped portions 204 and 209, formed between the thin portions 206, 206 and the heat dissipating portion 210 and formed to be recessed with respect to the contact surfaces 102 and 105. The inner surfaces of the stepped portions 204, 209 are respectively disposed between the contact surfaces 102, 105 and the inner walls 206, 207 being inner surfaces of the thin portions 202, 206 in the thickness direction of the case 24.

Since the case 24 includes the thin portions 202 and 206 thinner than the heat dissipating portion 210, on the outer circumference of the contact surfaces 102 and 105. Accordingly, when the semiconductor circuit 100 is inserted into the case 24 to bring the semiconductor circuit 100 and the case 24 into close contact, the thin portions 202 and 206 having small thickness are deformed without deformation of the contact surfaces 102 and 105. With this configuration, it is possible to bring the semiconductor circuit 100 and the contact surfaces 102 and 105 into close contact with each other with the adhesive sheet 23 interposed therebetween. With deformation of the contact surfaces 102 and 105, the heat transfer area obtained between the semiconductor circuit 100 and the contact surfaces 102 and 105 would be reduced, leading to reduction of the heat dissipation. In contrast, the case 24 enables heat transfer from the semiconductor circuit 100 to the case 24 to be performed on the contact surfaces 102 and 105 in close contact with the semiconductor circuit 100 with a wide contact area, making it possible to achieve the case 24 that can enhance the heat dissipation of the semiconductor circuit 100.

In addition, the case 24 and the semiconductor circuit 100 can be joined with each other by inserting the semiconductor circuit 100 into the case 24 and applying pressure by the pressing jig 305, leading to facilitation of joining and excellent productivity.

Furthermore, it is possible to circulate the cooling medium directly to the outside of the case 24 without separately preparing a partition wall covering the cooling medium, for example, a refrigerant flow path pipe. Accordingly, as in the semiconductor cooling apparatus 300 illustrated in FIGS. 14 to 15, the semiconductor circuit 100 inserted in the case 24 can be cooled with a small space occupancy volume. In addition, the use of the case 24 increases the degree of freedom in designing the flow path of the cooling medium, making it possible to cool the semiconductor circuit 100 even with severe installation space restrictions.

(2) The case 24 includes the opening portion 205 formed in an opening surface perpendicular to the heat dissipation surface on which the heat dissipating portion 210 and the thin portions 202 and 206 are formed. This enables insertion of the first retainer 301 from the opening portion 205 to fix the case 24.

(3) The opening portion 205 is formed in each of a pair of opening surfaces perpendicular to the heat dissipation surface on which the heat dissipating portion 210 and the thin portions 202 and 206 are formed. This enables fixation of both surfaces of the case 24 using different recesses, and enables processing of both surfaces of the case 24. Note that the recess 209 illustrated in FIG. 3 may be used for fixing the case 24. In this case, the shape of the end of the first retainer 301 may be changed to fit the recess 209.

(4) The semiconductor circuit 100 has a substantially flat plate shape. The heat dissipating portion 210 includes: the first contact surface coming in contact with a first contact surface of the semiconductor circuit 100, namely, the contact surface 102; and a second contact surface coming in contact with the second surface of the semiconductor circuit 100, namely, the contact surface 105. The thin portion 202 includes: a first thin portion formed so as to surround the first contact surface 102, exemplified by the thin portion 202 on the right side in FIG. 2; and a second thin portion formed so as to surround the second contact surface 105, exemplified by the thin portion 202 on the left side in FIG. 2. The recess 204 includes: a first recess formed between the first thin portion and the heat dissipating portion 210 and recessed with respect to the first contact surface, exemplified by the recess 204 on the right side in FIG. 2; and a second recess formed between the second thin portion and the heat dissipating portion 210 and recessed with respect to the second contact surface, exemplified by the recess 204 on the left side in FIG. 2.

With this configuration, when the case 24 is pressurized using the pressing jig 305 in a state where the semiconductor circuit 100 is inserted, the thin portions 202 and 206 on both sides of the case 24 are deformed. This enables both surfaces of the semiconductor circuit 100 to have a wide contact area with the case 24 without causing deformation of the contact surfaces 102 and 105.

(5) The heat dissipating portion 210 includes a plurality of first fin groups on the opposite side of the first contact surface 102, in which the virtual surface 103 formed by the end of the first fin group is parallel to the first contact surface 102. The heat dissipating portion 210 includes a plurality of second fin groups on the opposite side of the second contact surface 105, in which the virtual surface 106 formed by the end of the second fin group is parallel to the second contact surface 105.

Therefore, since the contact surfaces 101, 102, 104, and 105 are parallel to each other and the left and right end surfaces 103 and 106 are parallel to each other, uniform pressure is generated on the adhesive sheet 23. As a result, the adhesive sheet after joining has a high joining strength, with no joining defect such as peeling of the joint, leading to high joining reliability in the adhesive sheet 23. In addition, since the contact surfaces 101, 102, 104, and 105 are parallel to each other, it is possible to reduce the thickness of the adhesive sheet 23. This enables suppression of deterioration in heat transfer performance due to the presence of the adhesive sheet 23. In other words, with the use of the case 24, it is possible to improve the heat dissipation of the semiconductor circuit 100 to be inserted into the case 24.

(First Modification)

The arrangement of the stepped portion 204 and the fins 25 may be changed as follows.

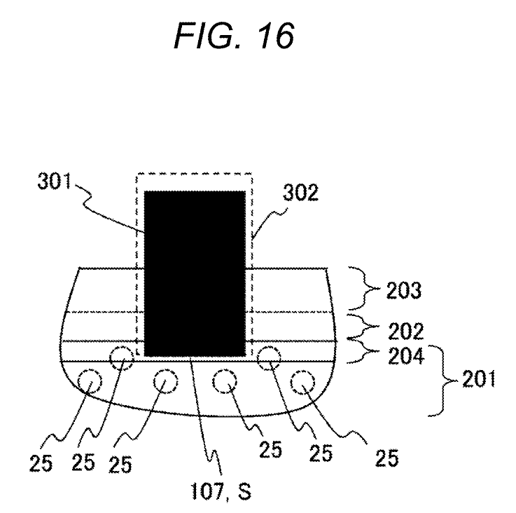

FIG. 16 is a diagram illustrating arrangement positions of the stepped portion 204 and the fins 25 in the first modification. As illustrated in FIG. 16, the stepped portion 204 may be provided on all sides of the boundary between the thick portion 201 and the thin portion 202. In this case, furthermore, the fins 25 may be disposed at the positions on the stepped portion 204 not sandwiched between the first retainer 301 and the second retainer 302, rather than being disposed at the positions on the stepped portion 204 sandwiched between the first retainer 301 and the second retainer 302.

(Second Modification)

The shape of the first retainer 301 may also be changed together with a change of the arrangement positions of the stepped portion 204 and the location of the fin 25 as follows.

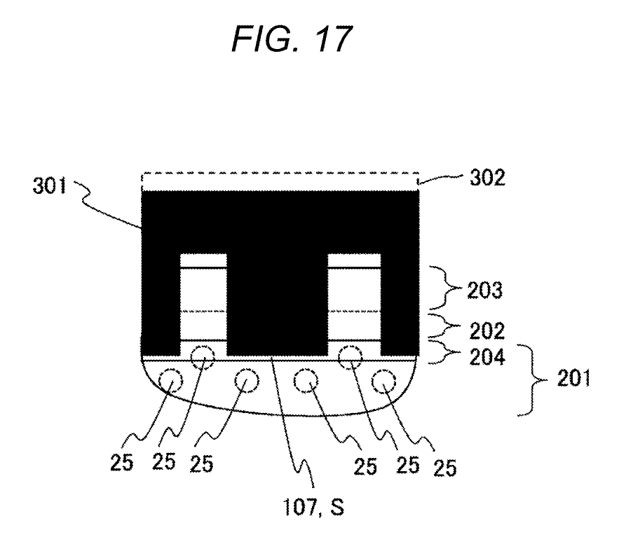

FIG. 17 is a diagram illustrating arrangement positions of the stepped portion 204 and the fins 25 in the second modification. As illustrated in FIG. 17, the stepped portion 204 may be provided on all sides of the boundary between the thick portion 201 and the thin portion 202. In this case, it is allowable to further allow the end of the first retainer 301 to be branched and to perform fixation by pinching portions except a portion where the fins 25 of the stepped portion 204 are arranged, using the first retainer 301 and the second retainer 302.

(Third Modification)

The contact surface 105 and the left end surface 106 are processed by the same method as the method used for the above-described contact surface 102 and the right end surface 103 so as to obtain similar effects. Moreover, it is allowable to fix the stepped portion 209 instead of fixing the stepped portion 204 described above. Alternatively, all the stepped portions 204 and 209 may be fixed to obtain the similar effects.

(Fourth Modification)

While the embodiment uses different shapes for the recess 204 and the recess 209 are different, the shapes of the recess 204 and the recess 209 are interchangeable, or may be identical. Moreover, other shapes that satisfy the following three conditions may also be used. The first condition is to have a thickness and shape achieving rigidity that can withstand cutting processing. The second condition is to have a thickness thicker than the thin portion 202. The third condition is to be recessed more than the contact surfaces 102, 105 with respect to the inside of the case 24 as a reference.

Each of the embodiments and modifications described above may be combined with each other.

While various embodiments and modifications have been described above, the present invention is not limited to these examples. Other aspects conceivable within the technical scope of the present invention are also included within the scope of the present invention.

### REFERENCE SIGNS LIST

23 adhesive sheet
24 case
25 fin
100 semiconductor circuit
101, 102, 104, 105 contact surface
103 right end surface
106 left end surface
201 thick portion
202 thin portion
204, 209 stepped portion
205 opening portion

1. A case into which a semiconductor circuit is inserted, the case comprising:
a heat dissipating portion having, on an inner side, a contact surface coming in contact with the semiconductor circuit;
a thin portion formed to surround the contact surface and formed to be thinner than the heat dissipating portion; and
a recess formed between the thin portion and the heat dissipating portion and recessed with respect to the contact surface,
wherein an inner surface of the recess is arranged between the contact surface and an inner surface of the thin portion in a thickness direction of the case.

2. The case according to claim 1,
further comprising an opening portion formed on a surface perpendicular to a surface on which the heat dissipating portion and the thin portion are formed.

3. The case according to claim 2,
wherein the opening portion has a first opening portion and a second opening portion each formed on each of a pair of surfaces perpendicular to the surface on which the heat dissipating portion and the thin portion are formed.

4. The case according to claim 1,
wherein the semiconductor circuit has a substantially flat plate shape,
the heat dissipating portion includes a first contact surface coming in contact with a first surface of the semiconductor circuit and a second contact surface coming in contact with a second surface of the semiconductor circuit,
the thin portion includes a first thin portion formed so as to surround the first contact surface and a second thin portion formed so as to surround the second contact surface, and
the recess includes: a first recess formed between the first thin portion and the heat dissipating portion, and recessed with respect to the first contact surface; and a second recess formed between the second thin portion and the heat dissipating portion, and recessed with respect to the second contact surface.

5. The case according to claim 4, wherein
the heat dissipating portion includes a plurality of first fin groups on a surface opposite to the first contact surface, with a virtual surface formed by an end of the first fin group being parallel to the first contact surface, and
the heat dissipating portion includes a plurality of second fin groups on a surface opposite to the second contact surface, with a virtual surface formed by an end of the second fin group being parallel to the second contact surface.

6. A semiconductor apparatus comprising:
a semiconductor circuit having a semiconductor element; and
a case to accommodate the semiconductor circuit,
wherein the case includes:
a heat dissipating portion having a contact surface coming in contact with the semiconductor circuit;
a thin portion formed to surround the contact surface and formed to be thinner than the heat dissipating portion; and
a recess formed between the thin portion and the heat dissipating portion and recessed with respect to the contact surface, and
an inner surface of the recess is arranged between the contact surface and an inner surface of the thin portion in a thickness direction of the case.

7. A method for manufacturing a case into which a semiconductor circuit is to be inserted, the method comprising
forming each of: a heat dissipating portion having, on an inner side, a contact surface coming in contact with the semiconductor circuit; a thin portion formed to surround the contact surface and formed to be thinner than the heat dissipating portion; and a recess formed between the thin portion and the heat dissipating portion and recessed with respect to the contact surface to be arranged so as to allow an inner surface of the recess to be arranged between the contact surface and an inner surface of the thin portion in a thickness direction of the case, so as to be formed individually in the case, and
performing cutting processing on the contact surface of the case in a state where the case is supported by a jig fixed in the recess.

8. The method for manufacturing a case according to claim 7,
wherein the heat dissipating portion includes a plurality of fins on an outer side, and
cutting processing is performed so that a virtual surface formed by ends of the plurality of fins is parallel to the contact surface.
